(19) United States
(12) Patent Application Publication
(10) Pub. No.: US 2013/0342231 A1
(43) Pub. Date: Dec. 26, 2013

(54) SEMICONDUCTOR SUBSTRATE WITH ONBOARD TEST STRUCTURE

(71) Applicants: Michael Alfano, Austin, TX (US); Joel Siegel, Brookline, MA (US); Michael Z. Su, Round Rock, TX (US); Bryan Black, Spicewood, TX (US); Neil McLellan, Austin, TX (US)

(72) Inventors: Michael Alfano, Austin, TX (US); Joel Siegel, Brookline, MA (US); Michael Z. Su, Round Rock, TX (US); Bryan Black, Spicewood, TX (US); Neil McLellan, Austin, TX (US)

(21) Appl. No.: 13/529,754

(22) Filed: Jun. 21, 2012

(51) Int. Cl. G01R 1/04; H05K 3/30; G01R 31/00

(52) U.S. Cl. 324/750.16; 324/756.05; 29/832

(57) ABSTRACT

Various interposers and methods of manufacturing related thereto are disclosed. In one aspect, a method of manufacturing is provided that includes fabricating a first test structure onboard an interposer that has a first side and second side opposite the first side. Additional test structures may be fabricated.

### BACKGROUND OF THE INVENTION

1. Field of the Invention

This invention relates generally to semiconductor processing, and more particularly to interposer-based semiconductor chip devices, and methods of making and using the same.

2. Description of the Related Art

Stacked semiconductor chip devices present a host of design and integration challenges for scientists and engineers. Common problems include providing adequate electrical interfaces between the stacked semiconductor chips themselves and between the individual chips and some type of circuit board, such as a motherboard or semiconductor chip package substrate, to which the semiconductor chips are mounted. Still another technical challenge associated with stacked semiconductor chips is testing.

Semiconductor interposers are sometimes used to serve as supporting and interconnect substrates for one or more semiconductor chips. A conventional semiconductor interposer consists of a silicon substrate and metallization to provide electrical pathways.

A process flow to transform bare semiconductor wafers into collections of interposers and chips and then mount the semiconductor chips on those interposers, and in-turn the interposers on circuit boards, involves a large number of individual steps. Because the processing and mounting of a semiconductor interposer proceeds in a generally linear fashion, that is, various steps are usually performed in a specific order, it is desirable to be able to identify defective parts as early in a flow as possible. In this way, defective parts may be identified so that they do not undergo needless additional processing. If, for example, the first semiconductor chip mounted to an interposer is revealed to be defective only after several other semiconductor chips are stacked thereon, then all of the material processing steps and the materials associated with the later-mounted chips may have been wasted.

Conventional interposers are two-sided devices, which require various processing steps to be performed on both principal sides. At various stages during the fabrication process flow, one or the other of the principal sides is covered by a protective substrate of one sort or another. While in place, these protective substrates cut off electrical testing access to the covered side of the interposer.

The present invention is directed to overcoming or reducing the effects of one or more of the foregoing disadvantages.

### SUMMARY OF EMBODIMENTS OF THE INVENTION

In accordance with one aspect of an embodiment of the present invention, a method of manufacturing is provided that includes fabricating a first test structure onboard an interposer that has a first side and second side opposite the first side.

In accordance with another aspect of an embodiment of the present invention, a method of processing is provided that includes performing a first electrical test on a first test structure onboard an interposer that has a first side and second side opposite the first side.

In accordance with another aspect of an embodiment of the present invention, an apparatus is provided that includes an interposer that has a first side and second side opposite the first side. A first test structure is onboard the interposer.

### BRIEF DESCRIPTION OF THE DRAWINGS

The foregoing and other advantages of the invention will become apparent upon reading the following detailed description and upon reference to the drawings in which:

FIG. 1 is an exploded pictorial view of an exemplary embodiment of a semiconductor chip device that includes an interposer that may be provided with one or more on-board test structures;

FIG. 2 is a sectional view of FIG. 1 taken at section 2-2;

FIG. 3 is a sectional view of another portion of the exemplary interposer depicted in FIG. 1;

FIG. 4 is a sectional view like FIG. 2, but depicting preliminary through-silicon-via formation;

FIG. 5 is a sectional view like FIG. 4, but depicting exemplary interconnect layers and test structure formation on one side of the interposer;

FIG. 6 is a sectional view like FIG. 5, but depicting exemplary electrical testing of an interposer using an onboard test structure;

FIG. 7 is a sectional view like FIG. 5, but depicting exemplary carrier substrate attachment;

FIG. 8 is a sectional view like FIG. 7, but depicting exemplary thinning of a body of the interposer;

FIG. 9 is a sectional view like FIG. 8, but depicting exemplary interconnect layers and test structure formation on an opposite side of the interposer and electrical testing using the onboard test structures;

FIG. 10 is a sectional view like FIG. 9, but depicting application of a carrier tape to the interposer;

FIG. 11 is a sectional view of a portion of the interposer of FIG. 1, depicting an exemplary onboard test structure;

FIG. 12 is a pictorial view of an alternate exemplary interposer-based test structure;

FIG. 13 is a sectional view of another portion of the interposer of FIG. 1, depicting another alternate exemplary onboard test structure; and

FIG. 14 is a flow chart depicting an exemplary method of making and using interposer-based test structures.

### DETAILED DESCRIPTION OF SPECIFIC EMBODIMENTS

Various interposers useful for mounting multiple semiconductor chips are disclosed. The interposers include onboard test structures that enable electrical testing of the interposers for various properties. Depending on the interposer configuration, a given test structure might be electrically accessible from one side or the other of the interposer. This flexibility in test structure placement enables electrical testing of the interposer at various stages of manufacture and assembly. Additional details will now be described.

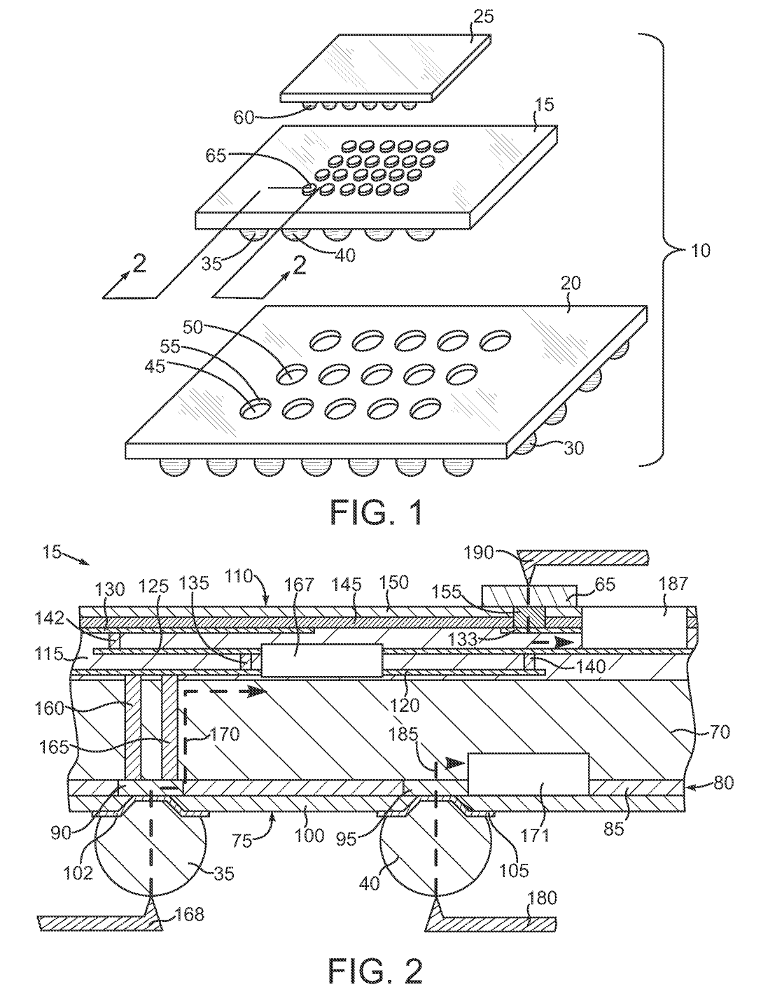

In the drawings described below, reference numerals are generally repeated where identical elements appear in more than one figure. Turning now to the drawings, and in particular to FIG. 1, therein is shown an exploded pictorial view of an exemplary embodiment of a semiconductor chip device 10 that includes an interposer 15 that may be provided with one or more on-board test structures (not visible) that will be depicted and described in more detail below. The interposer 15 may be mounted on a substrate 20 and a semiconductor chip 25 may be mounted on the interposer 15. In this way, the interposer 15 may be operable to transmit power, ground and signals between the semiconductor chip 25 and the underlying circuit board 30. The semiconductor chip device 10 may be used to implement a large number of different functions. Thus, the semiconductor chip 25 may be selected from numerous types of integrated circuits. Examples include microprocessors, graphics processors, combined microprocessor/graphics processors, application specific integrated circuits, memory devices, active optical devices, such as lasers, or the like, and may be single or multi-core. The semiconductor chip 25 may be constructed of bulk semiconductor, such as silicon or germanium, or semiconductor on insulator materials, such as silicon-on-insulator materials. The skilled artisan will appreciate that more than one semiconductor chip 25 may be mounted on the interposer 15 in a stacked and/or a side-by-side arrangement as desired.

The configuration of the interposer 15 is subject to great variety. For example, the interposer 15 may be simply another semiconductor chip as opposed to purely an interposer. If typically configured, the interposer 15 may consist of a substrate of a material(s) with a coefficient of thermal expansion (CTE) that is near the CTE of the semiconductor chip 25 and that includes plural internal conductor traces and vias for electrical routing. Various semiconductor materials may be used, such as silicon, germanium or the like. Silicon has the advantage of a favorable CTE and the widespread availability of mature fabrication processes. Of course, the interposer 15 could also be fabricated as an integrated circuit like the semiconductor chip 25. In either case, the interposer 15 could be fabricated on a wafer level or chip level process. Indeed, the semiconductor chip 25 could be fabricated on either a wafer or chip level basis, and then singulated and mounted to an interposer 15 that has not been singulated from a wafer. Singulation of the interposer 15 would follow mounting of the semiconductor chip 25. Therefore, as used herein, the term “interposer” is intended to mean a substrate with pass-through conductors, such as long vias. The interposer 15 includes plural electrical pathways to transmit power, ground and signals. A few of these pathways will be illustrated in subsequent figures.

Similarly, the substrate 20 may take on a variety of configurations. Examples include a semiconductor chip package substrate, a circuit card, another interposer, or virtually any other type of printed circuit board. Although a monolithic structure could be used for the substrate 20, a more typical configuration will utilize a buildup design. In this regard, the substrate 20 may consist of a central core upon which one or more buildup layers are formed and below which an additional one or more buildup layers are formed. The core itself may consist of a stack of one or more layers. If implemented as a semiconductor chip package substrate, the number of layers in the substrate 20 can vary from four to sixteen or more, although less than four may be used. So-called “coreless” designs may be used as well. The layers of the substrate 20 may consist of an insulating material, such as various well-known epoxies, interspersed with metal interconnects. A multi-layer configuration other than buildup could be used. Optionally, the substrate 20 may be composed of well-known ceramics or other materials suitable for package substrates or other printed circuit boards. The substrate 20 is provided with a number of electrical pathways to transmit power, ground and signals (not visible). To electrically interface with another electronic device, the substrate 20 may include plural interconnect structures 30, which may be balls of a ball grid array as shown, or optionally consist of a pin grid array, a land grid array or other types of interconnects.

The interposer 15 may interface electrically with the substrate 20 in a variety of ways. In the depicted embodiment, the interposer 15 may include plural interconnect structures, two of which are labeled 35 and 40, that are designed to interface electrically with corresponding conductor pads of the substrate 20, two of which are labeled 45 and 50. Here, the conductor pads 45 and 50 may be positioned beneath a top insulating film 55, which may be a solder mask or other type of insulating film. The interconnect structures 35 and 40 may be solder bumps, micro bumps, conductive pillars or the like. Exemplary solder materials include lead-based solders at or near eutectic proportions, such as about 63% Sn and 37% Pb. Lead-free examples include tin-silver (about 97.3% Sn 2.7% Ag), tin-copper (about 99% Sn 1% Cu), tin-silver-copper (about 96.5% Sn 3% Ag 0.5% Cu) or the like. These compositions may be varied. Micro bumps may be fabricated from gold, silver, platinum, palladium, copper, combinations of these or others. Conductive pillars may be made from the same materials.

The semiconductor chip 25 may interface electrically with the interposer 15 in a variety of ways. For example, the semiconductor chip 25 may include plural interconnect structures, one of which is labeled 60, designed to connect to plural conductor pads of the interposer 15, one of which is labeled 65. The interconnect structures 60 and 65 may be configured like and constructed of the same types of materials as the interconnect structures 35 and 40 and the conductor pads 45 and 50. The conductor pad 65 will be described in more detail in conjunction with FIG. 2.

Additional details of the interposer 15 may be understood by referring now to FIG. 2, which is a sectional view of FIG. 1 taken at section 2-2. Note that section 2-2 passes through a small portion of the interposer 15 that includes the solder structures 35 and 40 and the conductor pad 65. The following discussion of the interposer 15 in conjunction with FIG. 2 will be illustrative of other portions of the interposer 15 as well. The interposer 15 may consist of a substrate 70 sandwiched between various metallization and dielectric layers. For example, a side 75 of the interposer 15 may include an interconnect layer 80 consisting of a dielectric layer 85 interspersed with metallization structures 90 and 95 electrically connected to the solder structures 35 and 40, respectively, and a polymer film 100 composed of polyimide, benzocyclobutene or other polymer materials that caps the interconnect layer 80. Underbump metallization (UBM) structures 102 and 105 may be formed to provide a beneficial metallurgical bonding between the solder structures 35 and 40 and the conductor structures 90 and 95. The dielectric layer 85 may be composed of well-known dielectric materials such as silicon dioxide, silicon nitride, laminates of these or others. The conductor structures 90 and 95 may be composed of a variety of metallic materials such as copper, gold, silver, platinum, palladium, aluminum, combinations of these or others. In this illustrative embodiment, the UBM structures 102 and 105 may consist of a laminate of plural metallic layers. The number and composition of such layers may be tailored to a particular bumping process, such as printing or plating for example. For example, the UBM structures 102 and 105 might be constructed for printed solder bump conductor structures 35 and 40 as a series of layers applied to the interposer 15 in succession, such as an adhesion layer of sputtered titanium or titanium-tungsten, followed by a sputtered nickel-vanadium layer, and capped with a sputtered solder-wettable layer of copper or gold. However, in the event that a bump plating process is used to establish the later-formed conductor structures 35 and 40, then the UBM structures 102 and 105 may consist of an adhesion layer of the type described above, followed by a plating seed layer, such as copper deposited by electroless plating or sputter deposition, followed by a nickel or nickel-vanadium barrier layer of the type described above and capped with a plating bar of copper or the like. Still other compositions are envisioned.

Still referring to FIG. 2, at the opposite side 110 of the interposer 15, a metallization stack may be formed on the substrate 70 that may consist of plural dielectric films that are represented collectively by the single dielectric film 115 and multiple layers of metallization. Conductor traces 120 and 125 of the two lower metallization layers, respectively, are visible. In addition, two conductor traces 130 and 132 of the upper metallization layer are visible. These conductor traces 120, 125, 130 and 132 may function as so-called redistribution layer (RDL) structures. The conductor traces 120 and 125 may be electrically connected by way of conductive vias 135 and 140 for example. The conductor traces 125 and 130 may be similarly electrically connected by way of one or more conductive vias 142. The conductor traces 120, 125, 130 and 132 and vias 135, 140 and 142 may be fabricated from a variety of conductor materials such as copper, gold, silver, platinum, palladium, aluminum, combinations of these or others. The dielectric film or stack 115 may be composed of one or more layers of a variety of interlevel dielectric materials, such as tetra-ethyl-ortho-silicate, various other glasses, or so-called “low-K” materials with a K value less than about 3.0 or “ultra low-K” materials with a K value less than about 2.7 that both favor reduced parasitics between displaced conductor layers. Exemplary materials include, for example, porous carbon doped oxides (p-SiCOH), nano porous organosilicate and black diamond film. The top metallization layer that includes the conductor traces 130 and 133 may be coated with a passivation structure 145, which may be a unitary or laminate structure that may be composed of silicon dioxide, silicon nitride, polyimide, laminates of these or others. Finally, the passivation structure 145 may be topped with another polymer film 150, which may be the same composition as the polymer film 100. The conductor pad 65 may be electrically connected to the conductor traces 133 by way of a conductive via 155, which penetrates through the polymer layer 150 and the passivation structure 145. The via 155 may be constructed of the same materials as the vias 135, 140 and 142.

A variety of electrical pathways may be provided between the sides 75 and 110 of the interposer 15. For example, in this illustrative embodiment, the solder structure 35 is connected electrically to the conductor trace 120 by way of one or more through silicon vias (TSV), two of which are shown and labeled 160 and 165, respectively. It should be understood that the terms “TSV” is used generically herein, in that the substrate 70 may be composed of material(s) other than silicon, and even of insulating materials such as silicon dioxide, tetra-ethyl-ortho-silicate or others. The TSVs 160 and 165 may, like all the conductor structures disclosed herein, number in the scores, hundreds or more, and may be composed of a variety of materials, such as copper, tungsten, graphene, aluminum, platinum, gold, palladium, alloys of these or like. Clad structures are envisioned.

As noted above, the interposer 15 may be provided with one or more on-board test structures that facilitate the electrical testing of both sides 75 and 110 of the interposer 15 at various points during the fabrication process thereof. For example, a test structure 167 (schematically represented) may be fabricated in conjunction with, for example, the metallization conductor traces 120 and 125. A probe contact 168 can be applied to the interconnect structure 35 to facilitate assessment of one or more electrical properties of the interposer 15 by way of the electrical pathway through the solder structure 35 and the TSVs 160 and 165 and as represented by the dashed line 170. In addition, a test structure 171 may be fabricated at the interconnect layer 85 in electrical contact with the conductor structure 95 so that another probe contact 180 may form an electrical pathway 185 through the interconnect structure 40. In this way, a second point of probe access to the side 75 of the interposer 15 may be established and used to monitor the electrical behavior of, for example, the metallization structures in the interconnect layer 85. Diagnostic access to the side 110 of the interposer 15 may be possible by fabricating a test structure 187 in electrical contact with the conductor pad 65, in this case by way of the conductor trace 133. Another probe contact 190 may access the test structure 187 through the conductor pad 65 and to the test structure C to provide probe access at the side 110 of the interposer 15. The test structures 167, 171 and 187 may be fabricated in a large variety of arrangements. Additional details regarding some of these exemplary structures will be provided in more detail below.

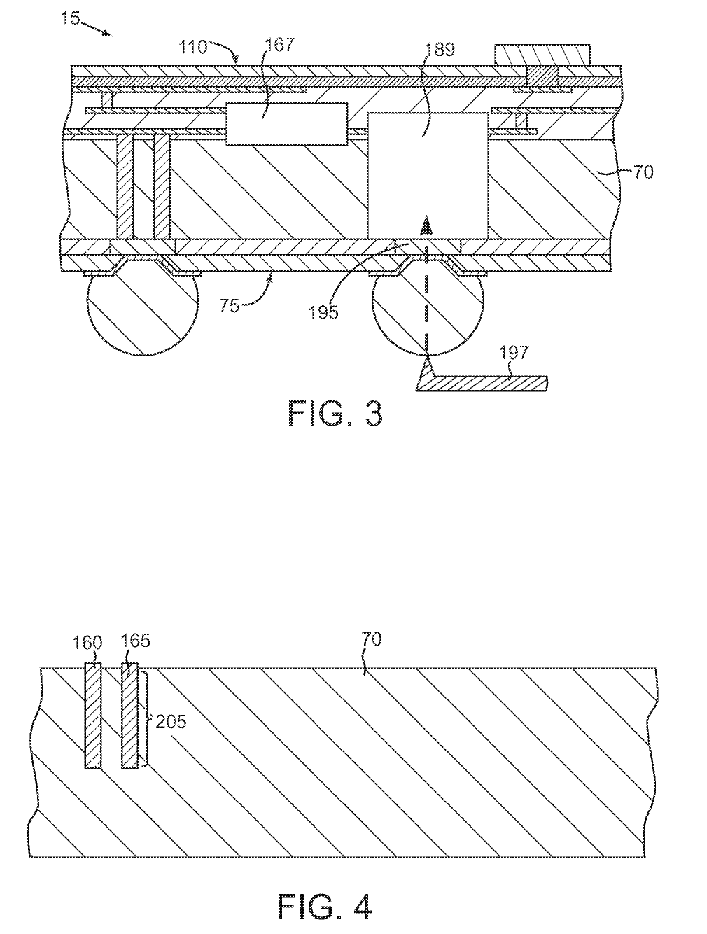

As noted above, a variety of test structures may be provided in a variety of locations and arrangements onboard the interposer 15. For example, and as shown in FIG. 3, which is a sectional view of another portion of the interposer 15, a test structure 189 may be fabricated proximate another interconnect structure 195, which may be like the interconnect structures 35 and 40 described above. Here, test structure 189 may be in electrical contact with the interconnect structure 195 but be fabricated through the substrate 70 of the interposer 15 and if desired in electrical contact with the conductor trace 120 to provide a test structure that mimics the electrical behavior of, for example, TSV structures within the substrate 70, and provides diagnostic access to interposer side 110 via the side 75 and a probe contact 197. Here also, another copy of the test structure 167 may be fabricated as described generally above in conjunction with FIG. 2.

An exemplary method of fabricating the interposer that incorporates electrical testing at various stages may be understood by referring now to FIGS. 4, 5, 6, 7, 8, 9 and 10 and initially to FIG. 4. Initially, the TSVs 160 and 165 may be fabricated in the substrate 70. At this stage, the substrate 70 has yet to undergo a thinning process, and thus may have a thickness of about 1,000 to 2,000 microns. The TSVs 160 and 165 may be fabricated using well-known TSV fabrication techniques. In particular, and using the TSV 165 as the exemplary structure, a material removal process may be used to form a deep trench 205 in the substrate 70 using an appropriate mask (not shown). The trench 205 may be formed by chemical etching with or without plasma enhancement or other material removal techniques. It might be possible to use laser ablation although care should be exercised to avoid excessive thermal heating. Depending upon the composition of the later-formed TSV 165, it may be necessary to apply a liner film (not shown) in the trench 205 in order to facilitate both adhesion to the substrate 70 as well as prevent migration of atoms, molecules or larger portions of the TSV 165 into the substrate 70. The liner layer may be composed of a variety of materials, such as silicon dioxide. Well-known CVD techniques with or without plasma enhancement may be used to deposit the liner layer. Following formation of the trench 205, the TSV 165 may be formed. A plating process used to form the TSV 165 may be a single step biased plating process or may be an unbiased seed layer plating process followed by a biased plating process as desired.

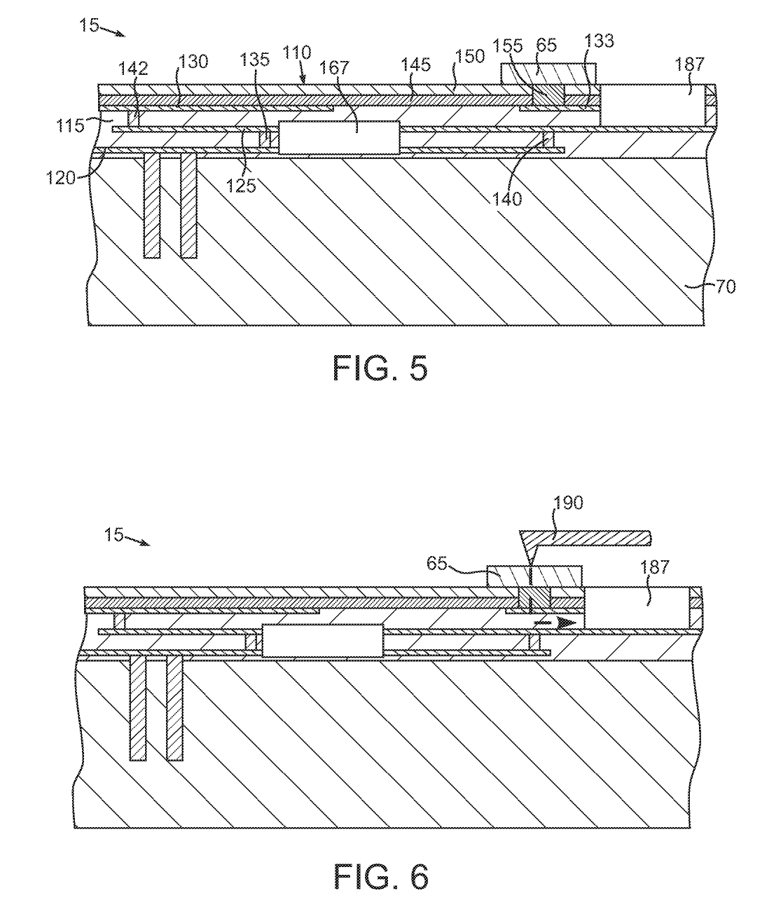

Next, and as depicted in FIG. 5, the combination of the dielectric stack 155 and the conductor traces 120, 125, 130 and 133, the conductive vias 135, 140 and 142, the polymer film 145, the passivation structure 150, the conductive via 155 and the conductor pad 65 may be fabricated on the semiconductor workpiece 200. The conductor traces 120, 125, 130 and 133 may be fabricated using well-known insulating material deposition and conductor material deposition and patterning techniques that may number over multiple layers depending upon the complexity of the interposer 15. For example, the interconnect layer that includes the conductor trace 120 may be applied by CVD, plating, PVD or the like and subsequently masked and etched to yield the conductor trace 120. Next a layer of interlevel dielectric material is applied over the conductor trace 120, masked and etched to yield via holes for the vias 135 and 140. Conductor material is placed in the via holes by plating or otherwise to yield the vias 135 and 140, and so on for the next level of metallization and dielectric. Of course the test structure 167 may be fabricated in conjunction with the steps used to fabricate, for example, the conductor traces 120 and 125, and the test structure 187 may be fabricated in conjunction with the steps used to fabricate, for example, the conductor traces 125 and 133. Again, additional details regarding exemplary physical implementation of the test structures 167 and 187, and other test structures disclosed herein will be provided in more detail below. The passivation structure 145 may be fabricated using well-known CVD or other techniques. The polymer layer 150 may be applied by spin coating and followed by one or more bake cycles. Finally, the via 155 may be fabricated using the techniques described above for the vias 135 and 140. In the event the polymer layer 150 includes photoactive compounds, the via hole for the via 155 may be formed by appropriate exposure and development. Finally, the conductor pad 65 may be fabricated using the same types of techniques used for the conductor traces 120 and 125. At this stage, the side 110 of the interposer is accessible for probe testing using the test structure 187 and the conductor pad 65. Thus, and as shown in FIG. 6, the probe contact 190 may be used to electrically stimulate the test structure 187 by way of the conductor pad 65 to provide a diagnostic for the interposer 15.

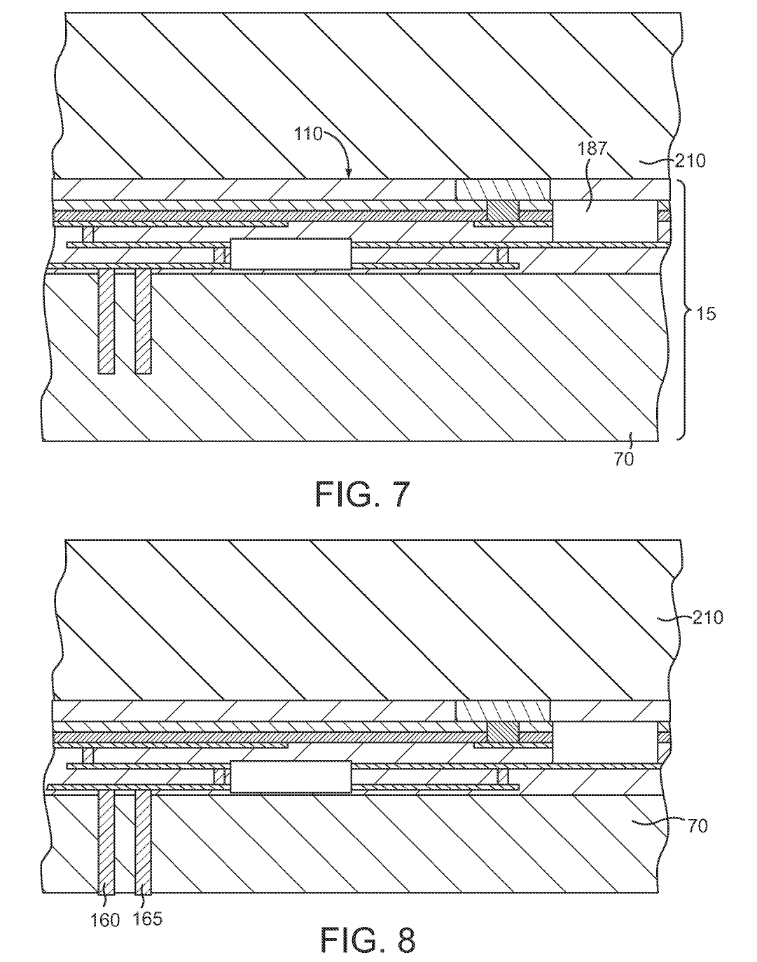

Next, and as shown in FIG. 7, a carrier substrate 210 is attached to the side 110 of the interposer 15 for handling purposes. At this stage, the side 110 of the interposer 15 is unavailable for electrical testing but because of the fabrication of test structure 187 proximate the side 110, electrical testing of the side 110 can precede the application of the carrier substrate 210. At this stage, the substrate 70 is still in a relatively thick state, perhaps on the order of 500 to 1,100 microns.

Next and as shown in FIG. 8, with the carrier substrate 210 in place, the substrate 70 is thinned up to the TSVs 160 and 165 to yield the semiconductor substrate 70 as shown. This thinning process may be performed using CMP or other material removal techniques as desired. The material removal process depicted in FIG. 8, particularly if CMP is used, may result in certain surface defects such as pits, gouges and scratches. Such surface defects can provide abrupt surfaces that create highly localized stress risers that may spawn crack formation. Accordingly, it may be desirable to perform a post thinning etch process in order to smooth out such surface defects. For example, a wet etch may be used to remove a fraction of a micron or so of the substrate 70. Well-known wet etchants suitable for etching silicon or whatever material happens to constitute the substrate 70 may be used, such as a buffered HF spin applied etch. The post-thinning thickness of the substrate 70 may be about 50 to 200 microns.

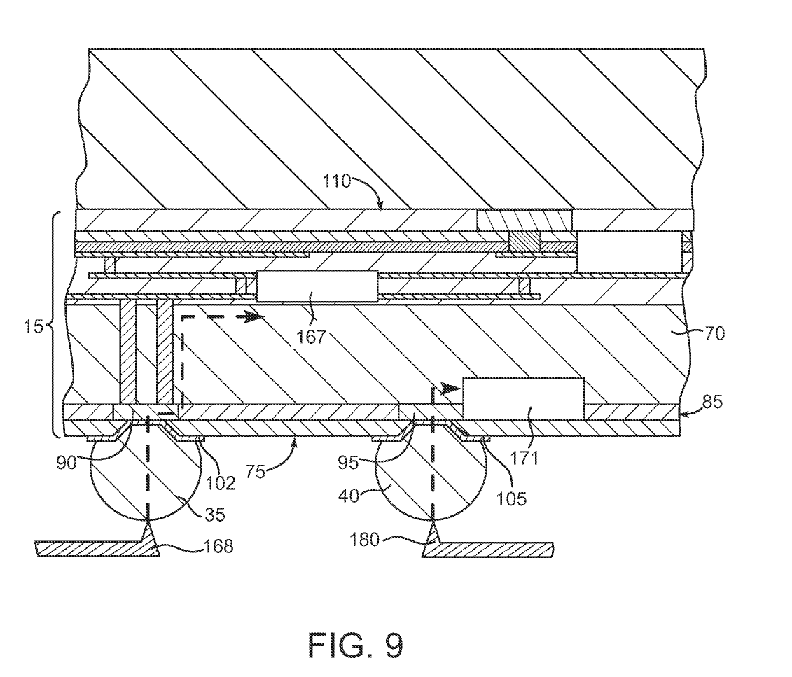

Next and as shown in FIG. 9, the interconnect layer 85 including the conductor structures 90 and 95, the polymer film 80, the solder structures 35 and 40 and the underlying UBM structures 95 and 100 may be fabricated on the semiconductor substrate 70 of the interposer 15 and again with the benefit of the carrier substrate 210. At this stage, while the side 110 of the interposer is unavailable for electrical testing, the side 75 of course is and thus probe contacts 168 and 180 may be used to perform electrical testing using test structures 167 and 171 to yield information about the side 110 as described above.

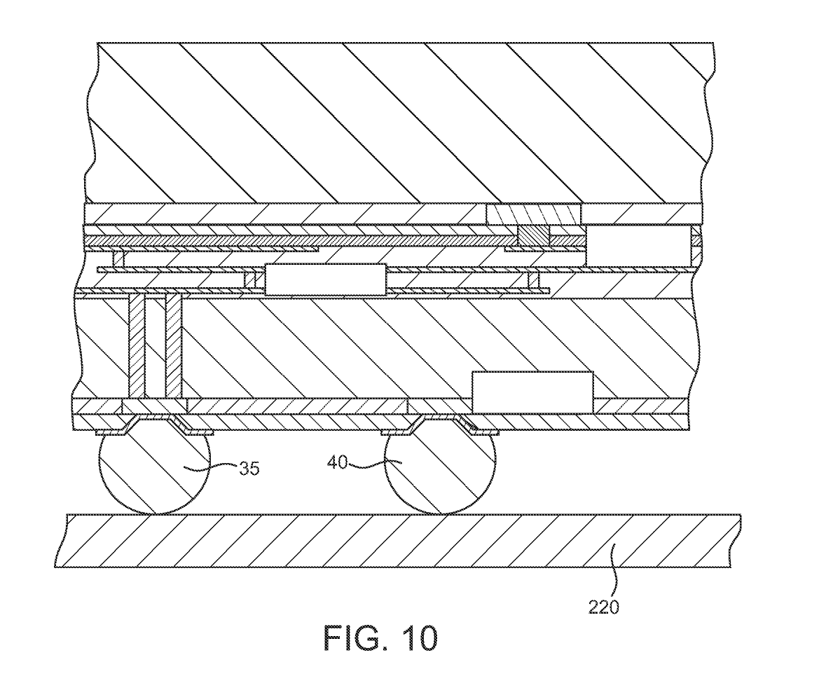

Next, and as shown in FIG. 10, a carrier tape 220 may be connected to the solder structures 35 and 40 and used as a protective barrier for both shipping and handling purposes. This may be beneficial in situations where subsequent processes such as additional testing, package assembly, etc. may be performed at different locations.

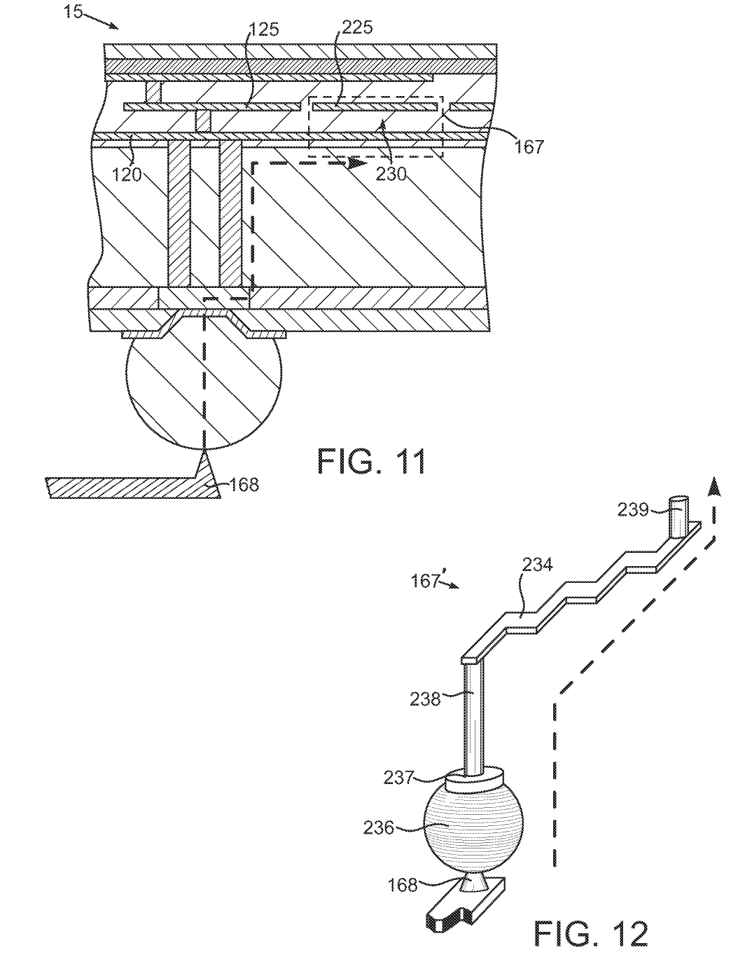

FIG. 11 depicts one exemplary physical implementation of the test structure 167 in the interposer 15. Here, the test structure 167 (delineated by the dashed box) may be a capacitor consisting of overlapping portions of the conductor trace 120 and another conductor trace 225 positioned in the same level as the conductor trace 125. With the probe contact 168 in place, the test structure 167 may be electrically tested to verify, for example, the capacitance of the capacitor. Such a measurement may be used to establish, for example, if the dielectric material in the gap 230 between the conductor trace 120 and the overlapping conductor trace 225 meets specifications. This represents merely one example of a possible physical implementation for the test structure 167.

FIG. 12 is a pictorial view of an alternate exemplary test structure 167′. Here, the alternate test structure 167′ may consist of a conductor trace 234 positioned in the same level as the conductor trace 120 shown in FIG. 11, but patterned as a resistor, in this case a zig-zag daisy chain-type metallization line. A solder structure 236, a conductor pad 237, a TSV 238, and another conductive via 239, (akin to the TSV's 160 and 165, the conductor pad 90, and the conductive via 135 described above and shown in FIG. 2), may be used to provide electrical access to the resistor trace 234 via the probe contact 168.

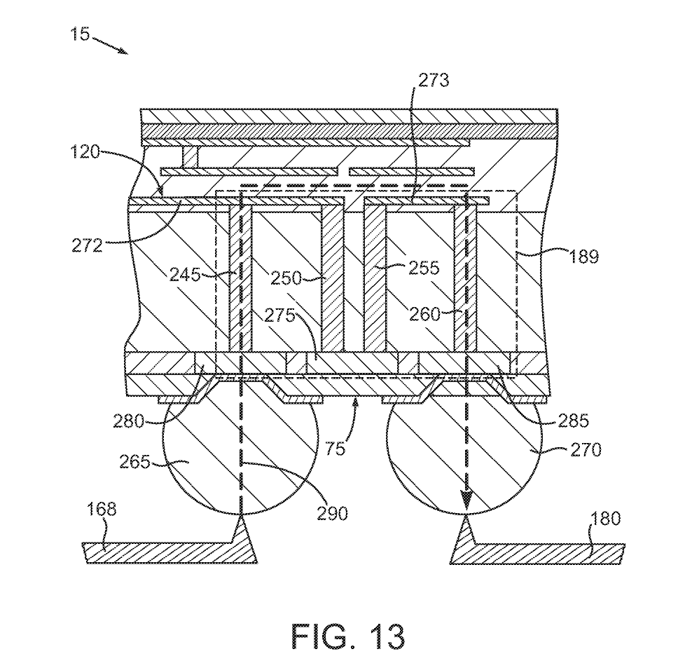

An exemplary physical implementation of the test structure 189 represented more schematically in FIG. 3 may be understood by referring now to FIG. 13. Here, the test structure 189 outlined by the dashed box may consist of a daisy chain arrangement of TSVs 245, 250, 255 and 260 in the interposer 15. The TSV 245 may be electrically connected to a solder structure 265 and the TSV 260 may be electrically connected to a solder structure 270, where the solder structure 265 and 270 may be like the solder structures 35 and 40 described above. The TSV 245 is electrically connected to the TSV 250 by a portion 272 of the conductor trace 120 and the TSVs 255 and 260 are electrically connected by another portion 273 of the conductor trace 120. Finally, the TSVs 250 and 255 may be connected by a metallization structure 275 proximate the interposer side 75. The metallization structure 275 may be formed along with conductor structures 280 and 285, which are formed as conductor pads for the solder structures 265 and 270. This daisy chain of conductor pads 280 and 285, TSVs 245, 250, 255 and 260 and portions of the metallization line 120 provide a test structure that is designed to mimic the properties of TSVs elsewhere within the interposer 15. Here, probe contacts 168 and 180 may be used to measure resistance or other electrical properties of the test structure 189, where the exemplary electrical pathways are indicated by the heavy dashed line 290.

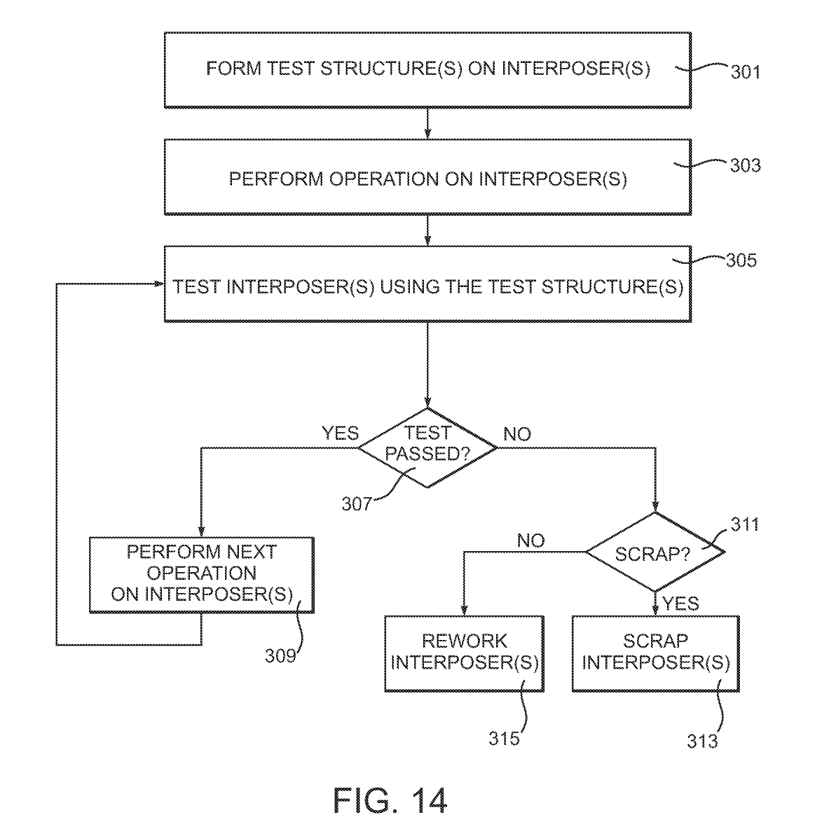

The onboard interposer test structures 167, 171, 187 and 189, etc., described herein may be used in a great variety of ways to facilitate process debug, testing and a variety of other activities. FIG. 14 depicts a flow chart of one exemplary process flow utilizing an interposer(s) onboard test structure(s). At step 301, a test structure(s) is formed on an interposer. This may entail the fabrication of the aforementioned test structures 167, 171, 187 and 189, etc. At step 303, some operation is performed on the interposer. This might include a process step, such as a material deposition or etching step, singulation from a wafer or perhaps the mounting of a semiconductor chip. At step 305, a test is performed on the interposer(s). For example, a material deposition or etching process may be performed on the interposer and thereafter the test performed on the interposer to determine post fabrication process step functionality. If the interposer passes the test at step 307, then a subsequent operation may be performed on the qualified interposer(s) at step 309. This might be, for example, another fabrication process such as a deposition or etching process or I/O connect or other type of step. Steps 305 and 307 may then be repeated. If however, at step 307, the tested interposer(s) do not pass, a decision may be made at step 311 to scrap the failed interposer(s). If so, the interposer(s) may be scrapped at step 313. Alternatively, a decision may be made at step 311 not to go to scrap, but instead go to a rework step or steps at step 315 in an attempt to rework the interposers. It should be understood that this process flow depicted in FIG. 14 and just described represents just one possible usage of the onboard interposer test structure(s).

While the invention may be susceptible to various modifications and alternative forms, specific embodiments have been shown by way of example in the drawings and have been described in detail herein. However, it should be understood that the invention is not intended to be limited to the particular forms disclosed. Rather, the invention is to cover all modifications, equivalents and alternatives falling within the spirit and scope of the invention as defined by the following appended claims.

What is claimed is:

1. A method of manufacturing, comprising:
fabricating a first test structure onboard an interposer having a first side and second side opposite the first side.

2. The method of claim 1, wherein the first test structure is positioned proximate the first side.

3. The method of claim 2, wherein the first test structure is electrically accessible from the second side.

4. The method of claim 2, wherein the first test structure is electrically accessible from the first side.

5. The method of claim 2, comprising fabricating a second test structure onboard the interposer and proximate the second side, the first test structure and the second test structure being electrically accessible from the first side.

6. The method of claim 2, comprising fabricating a through-silicon-via in the interposer, the first test structure being electrically accessible through the through-silicon-via.

7. The method of claim 1, wherein the first test structure comprises a capacitor or a resistor.

8. A method of processing, comprising:
performing a first electrical test on a first test structure onboard an interposer having a first side and second side opposite the first side.

9. The method of claim 8, wherein the first test structure is positioned proximate the first side, the method comprising electrically accessing the first test structure from the second side.

10. The method of claim 8, wherein the first test structure is positioned proximate the first side, the method comprising electrically accessing the first test structure from the first side.

11. The method of claim 8, comprising performing a second electrical test on a second test structure onboard the interposer and proximate the second side, the first electrical test and the second electrical test include electrically accessing the first test structure and the second test structure from the first side.

12. The method of claim 9, wherein the interposer comprises a through-silicon-via in the interposer, the first test structure being electrically accessible through the through-silicon-via.

13. The method of claim 8, wherein the first test structure comprises a capacitor or a resistor.

14. The method of claim 8, comprising performing a first operation on the interposer before performing the first electrical test.

15. The method of claim 14, comprising performing a second operation on the interposer after performing the first electrical test.

16. An apparatus, comprising:
an interposer having a first side and second side opposite the first side; and
a first test structure onboard the interposer.

17. The apparatus of claim 16, wherein the first test structure is positioned proximate the first side.

18. The apparatus of claim 17, wherein the first test structure is electrically accessible from the second side.

19. The apparatus of claim 17, wherein the first test structure is electrically accessible from the first side.

20. The apparatus of claim 17, comprising a second test structure onboard the interposer and proximate the second side, the first test structure and the second test structure being electrically accessible from the first side.

21. The apparatus of claim 17, comprising a through-silicon-via, the first test structure being electrically accessible through the through-silicon-via.

22. The apparatus of claim 16, wherein the first test structure comprises a capacitor or a resistor.
